(19) United States
(12) Patent Application Publication
(10) Pub. No.: US 2016/0099158 A1
(43) Pub. Date: Apr. 7, 2016

(54) METHOD FOR REMOVING METAL OXIDE

(71) Applicant: International Business Machines Corporation, Armonk, NY (US)

(72) Inventors: Rosa A. Orozco-teran, Wappingers Falls, NY (US); John Anthony Fitzsimmons, Poughkeepsie, NY (US); Russell Herbert Arndt, Fishkill, NY (US); Thamarai Selvi Davarajan, Albany, NY (US)

(21) Appl. No.: 14/507,008

(22) Filed: Oct. 6, 2014

(51) Int. Cl. H01L 21/3213; H01L 21/02; C09K 13/00

(52) U.S. Cl. CPC H01L 21/32134; C09K 13/00; H01L 21/02068

(57) ABSTRACT

The present invention relates to a method of selectively removing metal oxide, particularly tungsten oxide without etching the un-oxidized metal. The method removes metal oxide with little or no loss of the clean metal to improve the contact resistance for contact metal in semiconductor device fabrication. The method includes a step of exposing a substrate containing a tungsten oxide layer over a tungsten layer to a low oxygen aqueous ammonia solution to selectively remove the tungsten oxide layer. The low oxygen aqueous ammonia solution has an ammonia concentration in a range of about 0.01 M to about 2.0 M. The oxygen level in the solution is no more than 50 ppb. The solution may further contain a corrosion inhibitor and/or a compound having two or more carboxyl groups separated by at least one carbon atom.

### FIELD OF THE INVENTION

This invention relates generally to a method of metal oxide removal in a semiconductor process, and more particularly to a method of removing tungsten oxide without etching the un-oxidized tungsten using a low oxygen aqueous ammonia solution.

### BACKGROUND OF THE INVENTION

In the process of manufacturing semiconductor device, it is necessary to form conductive metal contacts in order to electrically connect various parts of the device to each other and to the external circuitry. In order to reduce the contact resistance, it is imperative to have a proper process step to clean the contact metal. The cleaning step may be used to remove various unwanted materials on the metal surface, within which one of the major components to remove is metal oxide. In prior technologies, a minimal amount of metal loss was acceptable to assure a clean metal contact. However, as the feature size of the metal contact continues shrinking, the cleaning process for metal contact has become more and more challenging resulting in more demanding requirements. The dimension of the current metal contact is so small that it is no longer acceptable even to have a minimal metal loss during the metal cleaning process. Therefore, there is a need to have a method to remove metal oxide with little or no attack to the contact metal.

Most of the teachings provided previously are methods to clean residues using acidic solutions which will not corrode the exposed metals, and do not provide a method to remove metal oxide with little or no attack to the metal underneath.

For example, Horiuchi et al., in U.S. Pat. No. 6,943,115, teach a method of manufacturing a semiconductor device where in the CMP slurry, cleaning as well as rinsing solutions rendered low in dissolved oxygen content so as to mitigate corrosion of exposed metal interconnect features especially those of copper. The method describes performing a rinsing step using water with low dissolved oxygen. Similarly, the dissolved level is preferably low as well in the cleaning solution and the solution used to formulate the CMP slurry to prevent the local loss of metal to corrosion.

In addition, Verhaverbeke et al., in U.S. Pat. No. 7,718,009, teach methods and solutions for cleaning fine features especially submicron copper patterns. In particular, acidic cleaning solutions with HF and sulfuric acid diluted with deoxygenated DI water are mentioned. The use of deoxygenated water in the cleaning solution is stated to increase the amount of time that the cleaning solution may be on a surface of the wafer substrate before portions of the surface become oxidized.

Further, Hong et al., in U.S. Pub. No. 2006/0234516, teach an acidic aqueous wet cleaning solution for removing residual photoresists and metal containing etching polymer residues from semiconductor devices after dry etching process. In order to prevent corrosion of underlying metallic features while removing the residues, a corrosion inhibitor is added to the solution.

### SUMMARY OF THE INVENTION

The present invention provides a method of selectively removing metal oxide, particularly tungsten oxide without etching the un-oxidized metal such as tungsten. Specifically, the invention provides a method of cleaning contact metal to reduce contact resistance for semiconductor device fabrication. The method of the present invention selectively removes metal oxide with little or no loss of the clean metal.

In one aspect, the present invention relates to a method of removing metal oxide including the steps of: providing a substrate containing a metal oxide layer over a metal layer, exposing the substrate to a low oxygen aqueous ammonia solution to selectively remove the metal oxide layer, and rinsing the substrate with a de-ionized (DI) water. Preferably, the DI water is a low oxygen DI water.

In another aspect, the present invention relates to a method of removing metal oxide including the steps of: providing a substrate containing a metal oxide layer over a metal layer, exposing the substrate to a low oxygen HF/organic acid solution, exposing the substrate to a low oxygen aqueous ammonia solution to selectively remove the metal oxide layer, and rinsing the substrate with a DI water. Preferably, the DI water is a low oxygen DI water.

The composition of the low oxygen aqueous ammonia solution has an ammonia concentration in a range of about 0.01 M (mole/liter) to about 2 M, preferably in a arrange of about 0.1 M to about 1M, and more preferably in a range of about 0.2 M to about 0.8 M. The low oxygen level in the low oxygen aqueous ammonia solution is achieved through either sparging the solution with nitrogen or argon, or vacuum degas of an aqueous ammonia solution, and the oxygen level in the low oxygen aqueous ammonia solution is no more than 50 ppb (part per billion), preferably no more than 5 ppb, and more preferably no more than 1 ppb.

The temperature of exposing the substrate to the low oxygen aqueous ammonia solution is at about 20° C. to about 95° C. The exposure time is about 10 seconds to about 300 seconds, preferably about 20 seconds to about 200 seconds, and more preferably about 30 seconds to about 120 seconds.

The low oxygen aqueous ammonia solution may contain a corrosion inhibitor which may include amine hydrocarbons, particularly heterocyclic amines, and the corrosion inhibitor may be selected from the following exemplary compounds: triazole compound, benzotriazole compound, imidazole compound, tetrazole compound, thiazole compound, oxazole compound, pyrazole compound, and pyridine compound.

After exposing the substrate to the low oxygen aqueous ammonia solution to selectively remove the metal oxide layer, the substrate is then rinsed with a DI water. The DI water may contain carbon dioxide. Preferably, the DI water is a low oxygen DI water. The oxygen level in the low oxygen DI water is no more than 50 ppb, preferably no more than 5 ppb, and more preferably no more than 1 ppb.

The oxygen level in the low oxygen HF/organic acid solution is no more than 50 ppb, preferably no more than 5 ppb, and more preferably no more than 1 ppb. The HF concentration in the low oxygen HF/organic acid solution is in a range of about 0.01% to about 0.1%, and preferably in a range of about 0.03% to about 0.05% based on the total weight of the low oxygen HF/organic acid solution. The organic acid concentration in the low oxygen HF/organic acid solution is in a range of about 0.05% to about 5%, and preferably in a range of about 0.5% to about 2% based on the total weight of the low oxygen HF/organic acid solution. The temperature of exposing the substrate to the low oxygen HF/organic acid solution is at about 20° C. to about 95° C., and preferably at about 50° C. to about 70° C. The exposure time is about 5 seconds to about 120 seconds, and preferably about 10 seconds to about 60 seconds.

The organic acid in the low oxygen HF/organic acid solution preferably contain a compound having two or more carboxyl groups separated by at least one carbon atom, and the compound may be selected from the following exemplary compounds: malonic acid, succinic acid, glutaric acid, adipic acid, citric acid, isocitric acid, and 1-hydroxy-1,1,2-ethanetricarboxylic acid, and 1,2,3,4-butanetetracarboxylic acid. Optionally, the low oxygen aqueous ammonia solution may contain the organic acid described above.

### BRIEF DESCRIPTION OF THE DRAWINGS

FIG. 1 is a flow chart of a method to selectively remove the metal oxide layer by exposing the substrate to a low oxygen aqueous ammonia solution according to one embodiment of the present invention.

FIG. 2 is a flow chart of a method to selectively remove the metal oxide layer by exposing the substrate to a low oxygen HF/citric acid solution, then exposing the substrate to a low oxygen aqueous ammonia solution according to one embodiment of the present invention.

FIG. 3 is a schematic cross-sectional diagram of a contact hole structure over a semiconductor substrate illustrating the result of exposing the substrate to a low oxygen aqueous ammonia solution to selectively remove the tungsten oxide layer according to one embodiment of the present invention.

FIG. 4 is a schematic cross-sectional diagram of a contact hole structure over a semiconductor substrate illustrating the result of exposing the substrate to an incompletely sparged aqueous ammonia solution to remove the tungsten oxide layer according to one embodiment of the present invention.

FIG. 5 is a schematic cross-sectional diagram of a contact hole structure over a semiconductor substrate illustrating the result of exposing the substrate to a low oxygen HF/citric acid solution, then exposing the substrate to a low oxygen aqueous ammonia solution to selectively remove the tungsten oxide layer according to one embodiment of the present invention.

FIG. 6 is a schematic cross-sectional diagram of a contact hole structure over a semiconductor substrate illustrating the result of exposing the substrate to a hydrogen peroxide and sulfuric acid mixture to remove the tungsten oxide layer according to one embodiment of the present invention.

### DETAILED DESCRIPTION OF PREFERRED EMBODIMENTS

This invention relates to a method of removing metal oxide in a semiconductor process. There are many metals used in the electronic industry including their alloys, and a few of them are listed here: aluminum, copper, cobalt, tungsten, tantalum, nickel, gold, silver, cobalt, palladium, platinum, chromium, ruthenium, rhodium, iridium, hafnium, titanium, molybdenum, tin, gallium, indium, lanthanum, cerium, neodymium, samarium, niobium and europium. Many of these metals having metal oxides on the surface may need to be removed to restore the clean metal surface. In the process of manufacturing semiconductor device, it is necessary to form conductive metal contacts in order to electrically connect various parts of the device to each other and to the external circuitry. Some of the metals may be used for the metal contacts are aluminum, copper, tungsten, titanium, tantalum, molybdenum, and their alloys thereof. It is imperative to remove any metal oxides formed on the surface of these metals to improve contact resistance for the metal contacts. The present invention accordingly provides a method to remove these oxides, more particularly a method of removing tungsten oxide without etching the un-oxidized tungsten using a low oxygen aqueous ammonia solution.

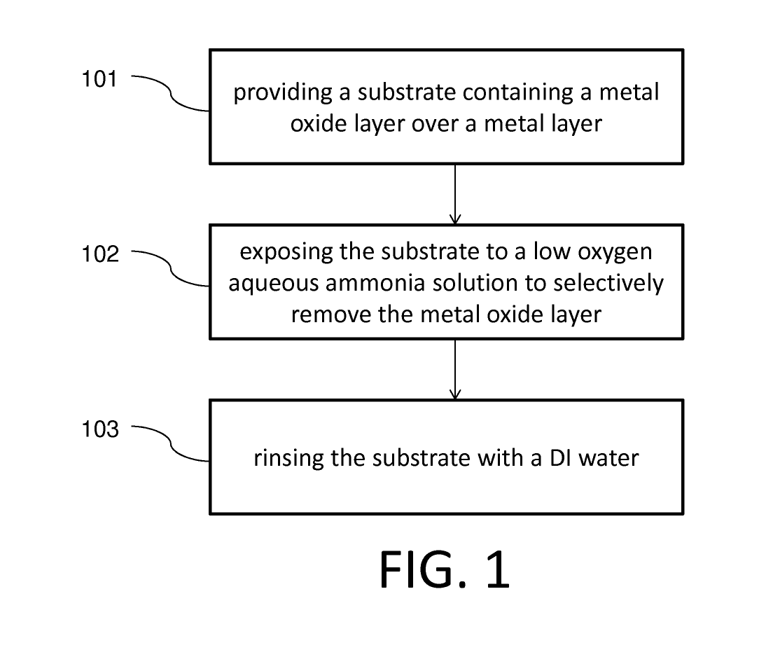

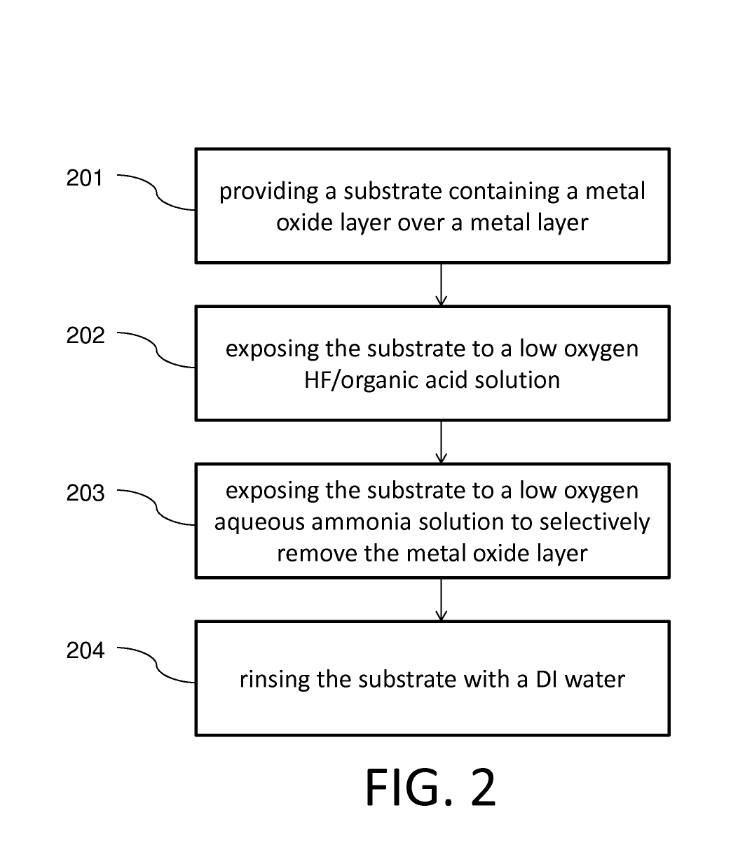

Embodiment of the present invention includes a method that may be used to remove metal oxide without etching the un-oxidized metal, such as but not limited to tungsten oxide. The method includes the steps of: providing a substrate containing a metal oxide layer over a metal layer, exposing the substrate to a low oxygen aqueous ammonia solution to selectively remove the metal oxide layer, and rinsing the substrate with a DI water. Embodiment of the present invention also includes a method which includes the steps of: providing a substrate containing a metal oxide layer over a metal layer, exposing the substrate to a low oxygen HF/organic acid solution, exposing the substrate to a low oxygen aqueous ammonia solution to selectively remove the metal oxide layer, and rinsing the substrate with a DI water. These two methods are described in the flow charts of FIG. 1 and FIG. 2. At block 101 of FIG. 1, a substrate containing a metal oxide layer over a metal layer is provided. At block 102 of FIG. 1, the substrate is exposed to a low oxygen aqueous ammonia solution to selectively remove the metal oxide layer. The composition of the low oxygen aqueous ammonia solution may have an ammonia concentration in a range of about 0.01 M to about 2 M, preferably in a arrange of about 0.1 M to about 1M, and more preferably in a range of about 0.2 M to about 0.8 M. The oxygen level in the low oxygen aqueous ammonia solution may be no more than 50 ppb, preferably no more than 5 ppb, and more preferably no more than 1 ppb. At block 103 of FIG. 1, the substrate after exposed to the low oxygen aqueous ammonia solution is then rinsed with a DI water. At block 201 of FIG. 2, a substrate containing a metal oxide layer over a metal layer is provided. At block 202 of FIG. 2, the substrate is exposed to a low oxygen HF/organic acid solution. The oxygen level in the low oxygen HF/organic acid solution may be no more than 50 ppb, preferably no more than 5 ppb, and more preferably no more than 1 ppb. The HF concentration in the low oxygen HF/organic acid solution may be in a range of about 0.01% to about 0.1%, and preferably in a range of about 0.03% to about 0.05% based on the total weight of the low oxygen HF/organic acid solution. The organic acid concentration in the low oxygen HF/organic acid solution may be in a range of about 0.05% to about 5%, and preferably in a range of about 0.5% to about 2% based on the total weight of the low oxygen HF/organic acid solution. At block 203 of FIG. 2, the substrate after exposed to the low oxygen HF/organic acid solution is further exposed to a low oxygen aqueous ammonia solution to selectively remove the metal oxide layer. At block 204 of FIG. 2, the substrate after exposed to the low oxygen aqueous ammonia solution is then rinsed with a DI water. The sequences of the steps in these charts are preferred. However, the invention is not limited to the performance of these steps with the sequences or orders presented in these charts. Many steps may also be applied to the substrate before, between or after the steps shown in the charts.

Since a semiconductor substrate may contain multiple layers, it is understood that one or more layers may exist above the metal oxide layer and one or more layers may exist under the metal layer on the substrate during the above process steps. It is also understood that these layers may exist only in some region or may contain opening(s) in some region on the substrate. The substrate is suitably any substrate conventionally used in the semiconductor process involving contact metal. For example, the substrate can be silicon, silicon oxide, aluminum-aluminum oxide, gallium arsenide, ceramic, quartz, copper or any combination thereof, including multilayers. The substrate can include one or more semiconductor layers or structures and can include active or operable portions of semiconductor devices. The layer above the metal oxide layer or below the metal layer may be a metal conductor layer, a ceramic insulator layer, a semiconductor layer or other material depending on the stage of the manufacture process and the desired material set for the end product.

Many steps may be applied to the substrate before, between or after the steps of the method of the present invention, which include but not limited to the steps of semiconductor doping, reactive ion etching, insulator deposition, metal deposition, photoresist processing, metal electroplating, chemical mechanical polishing (CMP), chemical vapor deposition (CVD), wet etching, and residue cleaning.

In prior technologies, a minimal amount of metal loss was acceptable to assure a clean metal contact during metal oxide removal. The minimal amount of metal loss is a loss of tens of angstroms of metal film. Now, the dimension of the current metal contact is so small that it is not acceptable even to have a minimal metal loss during the metal cleaning process. For example, in many prior technologies, it was acceptable to remove tens of angstroms of contact metal to assure a clean contact; however, advanced technologies severely limit acceptable metal loss to less than 10 angstroms. Thus, prior cleans removed too much metal for advanced technologies creating a need for advanced cleans that remove less than 10 angstroms of metal and yet provides good contact resistance. The present invention provides a step of selectively removing tungsten oxide without etching the un-oxidized tungsten by exposing the substrate to a low oxygen aqueous ammonia solution. Typically, the composition of the low oxygen aqueous ammonia solution has an ammonia concentration in a range of about 0.01 M to about 2 M, preferably in a arrange of about 0.1 M to about 1M, and more preferably in a range of about 0.2 M to about 0.8 M according to embodiments of the present invention. The low oxygen level in the low oxygen aqueous ammonia solution may be achieved by a means such as sparging or vacuum degas. Sparging may be achieved by passing a flow of inert gas, such as nitrogen or argon through a dispersion device to increase surface area to maximize solution contact. Typical condition is a flow of 300 sccm (standard cubic centimeters per minute) for minimum 5 minutes per liter of solution during chemical recirculation in a sealed loop. Alternatively, a vacuum degas membrane system may be used to degas the system. Typically, the solution is vacuum degassed for minimum 3 minutes per liter of solution before dispense. The oxygen level in the low oxygen aqueous ammonia solution may be no more than 50 ppb, preferably no more than 5 ppb, and more preferably no more than 1 ppb. The step of exposing the substrate to the low oxygen aqueous ammonia solution to selectively remove the metal oxide layer can apply any known technique, such as dipping in a bath containing the solution, dispensing the solution onto the substrate, or preferably spraying the solution on the substrate. Typically, the solution is sprayed at a temperature of about 20° C. to about 95° C. The spray time may be about 10 seconds to about 300 seconds, preferably about 20 seconds to about 200 seconds, and more preferably about 30 seconds to about 120 seconds.

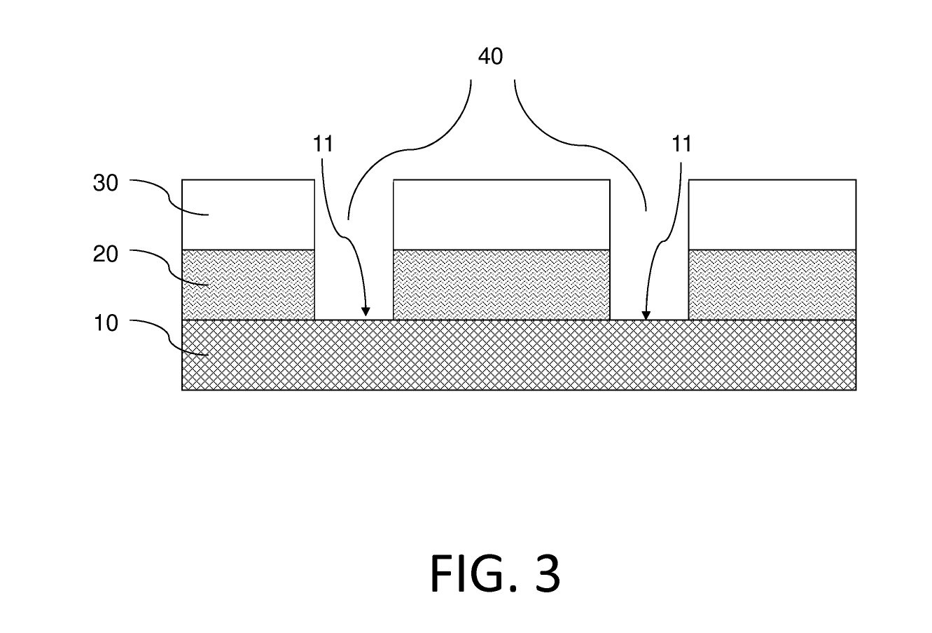

The low oxygen aqueous ammonia solution in the present invention effectively removes tungsten oxide without etching the un-oxidized tungsten, while an incompletely degassed aqueous ammonia solution (about 200 ppb oxygen level) with oxygen level higher than a fully sparged solution (<50 ppb oxygen level) exhibits some attack on the underlying tungsten. The low oxygen aqueous ammonia solution in the present invention operates at the reduction potential in a range about −0.9 V to −0.1 V vs. SCE and at a pH range about 11.5 to 15. In view of the published Pourbaix diagram of tungsten with water (U.S. Pat. No. 8,377,824, FIG. 3), the tungsten would get oxidized by water and dissolved to form WO₄²⁻in water at this pH range. The Poubaix diagram indicates that an oxidation and dissolution of tungsten metal by water would thermodynamically occur in the range about −0.9 V to −0.1 V vs. SCE and at a pH range about 11.5 to 15 of the present invention, thus it would predict a failure of the present invention. The prediction is based on the assumption that the reaction would occur instantly to reach the thermodynamic equilibrium. The unexpected successful results indicate that excluding other oxidation sources such as oxygen in the low oxygen aqueous ammonia solution produces a kinetically favorable condition where no oxidation on tungsten occurs within the exposed time range of the present invention.

To prevent re-oxidation of tungsten, the low oxygen aqueous ammonia solution may contain a corrosion inhibitor. Once the metal oxide is removed to expose the clean metal surface to the solution, the corrosion inhibitor may absorb or bind to the metal surface and protect the clean metal from re-oxidation. After the cleaning process, the corrosion inhibitor is then removed to restore the pure metal surface. The removing process may be vacuum degassing/sublimation or using reactive pre-clean step before metallization. Examples of the corrosion inhibitor may include amine hydrocarbons, particularly heterocyclic amines. The corrosion inhibitor may be selected from the following exemplary compounds: triazole compound, benzotriazole compound, imidazole compound, tetrazole compound, thiazole compound, oxazole compound, pyrazole compound, and pyridine compound. The concentration of the corrosion inhibitor may be in a range of about 10 ppm (part per million) to about 500 ppm, and preferably in a range of about 25 ppm to about 125 ppm. On the other hand, it is understood that in some instance, a concentration in a range of greater 1000 ppm may be used to avoid surface re-oxidation for extending the delay time between the current clean steps and subsequent process step.

After exposing the substrate to the low oxygen aqueous ammonia solution to selectively remove the metal oxide layer, the substrate is then rinsed with a DI water. Preferably, the DI water is a low oxygen DI water. The low oxygen level in the low oxygen DI water may be achieved by a means, such as sparging or vacuum degas. The oxygen level in the low oxygen DI water may be no more than 50 ppb, preferably no more than 5 ppb, and more preferably no more than 1 ppb. The DI water rinse may be carried out by dipping the substrate in a bath containing the DI water, dispensing the DI water onto the substrate, or spraying the DI water onto the substrate. The DI water will then remove any residual low oxygen aqueous ammonia solution from the substrate. To minimize any electrostatic charging effect during this DI water rinse to remove any residual low oxygen aqueous ammonia solution, the DI water may contain carbon dioxide. The carbon dioxide level in the DI water may be controlled by solution resistivity to a range of about 40,000 ohm-cm to about 400,000 ohm-cm standard resistivity, preferably about 50,000 ohm-cm to about 300,000 ohm-cm.

Many steps may be applied to the substrate before the present inventive steps to selectively remove the metal oxide layer, for example photoresist processing and reactive ion etching. These process steps may create some residues on the surface of the metal oxide, which may have to be removed to enhance the effectiveness of the removal of the metal oxide layer with the low oxygen aqueous ammonia solution. Therefore, the present invention includes a method which comprises the steps of: providing a substrate containing a metal oxide layer over a metal layer, exposing the substrate to a low oxygen HF/organic acid solution, exposing the substrate to a low oxygen aqueous ammonia solution to selectively remove the metal oxide layer, and rinsing the substrate with a DI water. Preferably, the DI water is a low oxygen DI water. The low oxygen level in the low oxygen HF/organic acid solution may be achieved by a typical means, such as sparging or vacuum degas. The oxygen level in the low oxygen HF/organic acid solution may be no more than 50 ppb, preferably no more than 5 ppb, and more preferably no more than 1 ppb. The HF concentration in the low oxygen HF/organic acid solution may be in a range of about 0.01% to about 0.1%, and preferably in a range of about 0.03% to about 0.05% based on the total weight of the low oxygen HF/organic acid solution. The organic acid concentration in the low oxygen HF/organic acid solution may be in a range of about 0.05% to about 5%, and preferably in a range of about 0.5% to about 2% based on the total weight of the low oxygen HF/organic acid solution. The step of exposing the substrate to a low oxygen HF/organic acid solution can apply any known technique, such as dipping in a bath containing the solution, dispensing the solution onto the substrate, or preferably spraying the solution on the substrate. Typically, the solution is sprayed at a temperature of about 20° C. to about 95° C., and preferably at about 50° C. to about 70° C. The spray time may be about 5 seconds to about 120 seconds, and preferably about 10 seconds to about 60 seconds.

The low oxygen HF/organic acid solution may contain a chelating organic acid including a compound having two or more carboxyl groups separated by at least one carbon atom. The exemplary compounds of these carboxylic acid compounds may contain dicarboxylic acid such as malonic acid, succinic acid, glutaric acid, and adipic acid; may contain tricarboxylic acid such as citric acid, isocitric acid, and 1-hydroxy-1,1,2-ethanetricarboxylic acid; and may contain tetracarboxylic acid such as 1,2,3,4-butanetetracarboxylic acid. Optionally, the low oxygen aqueous ammonia solution may contain the organic acid described above.

FIG. 3 exhibits the result of one of our preferred embodiments of the present invention, and is a schematic cross-sectional diagram of a contact hole structure over a semiconductor substrate, within which the substrate has been exposed to a low oxygen aqueous ammonia solution to selectively remove the tungsten oxide layer and rinsed with DI water. Since the drawing is intended for illustrative purpose, the drawing is not necessary drawn to scale. The drawing also only shows a few top layers of the multilayer stack of the entire semiconductor substrate. FIG. 3 shows a structure includes a tungsten layer 10, an interlayer dielectric A (ILD A) layer 20, an interlayer dielectric B (ILD B) layer 30, contact hole openings 40, and tungsten surfaces within contact holes 11. The tungsten layer 10 may be deposited to a semiconductor substrate (not shown in the drawing) with various deposition processes including but not limited to: physical vapor deposition, chemical vapor deposition and electrochemical deposition. The ILD A layer 20 and the ILD B layer 30 may be deposited onto the semiconductor substrate (not shown in the drawing) over the tungsten layer 10 with various deposition processes including but not limited to: evaporation, sputtering, plasma deposition, thermal oxidation, chemical vapor deposition, electrophoresis, spin on, spray on, silk screening, roller coating, and offset printing. The contact holes 40 may be created by reactive ion etching through the ILD A layer 20 and ILD B layer 30. Before applying the method of the present invention, the tungsten surfaces within contact holes may contain a tungsten oxide layer with various thicknesses. The substrate is exposed to a low oxygen aqueous ammonia solution having an ammonia concentration in a range of about 0.01 M to about 2 M and oxygen level no more than 50 ppb for about 10 to about 300 seconds to selectively remove the tungsten oxide layer without etching the un-oxidized tungsten layer 10. After exposing the substrate to the low oxygen aqueous ammonia solution to selectively remove the metal oxide layer, the substrate is then rinsed with a low oxygen DI water. The low oxygen DI water may contain carbon dioxide. FIG. 3 shows the result after these steps indicating no apparent film loss of underlying tungsten with the relatively unchanged tungsten surfaces within contact holes 11. One specific example is given below to illustrate this embodiment of the present invention. Since this example is given for illustrative purpose only, the invention is not limited to the specific details of the example.

### EXAMPLE 1

A 12 inch silicon wafer containing a tungsten layer, a tungsten oxide layer, two dielectric layers, and contact hole openings was placed in a sealed spin/rinse chamber atmospherically controlled to be low oxygen. A low oxygen aqueous ammonia solution was then dispensed onto the wafer at a rate of 1 liter/minute for one minute under typical single wafer spin/etch conditions. The concentration of the ammonia solution was 0.7 M. This ammonia solution had been prior sparged with nitrogen to achieve a level of <50 ppb dissolved oxygen before dispensing on the wafer. After dispensing the low oxygen aqueous ammonia solution, the wafer was rinsed for 60 seconds with a low oxygen DI water containing carbon dioxide, and was spun dry before exiting the atmospherically controlled chamber. The DI water had a resistivity of 200,000 ohm-cm. The tungsten oxide layer was removed without apparent film loss of the underlying tungsten layer as demonstrated in a cross sectioned TEM (transmission electron microscope) image of the wafer after the above processing.

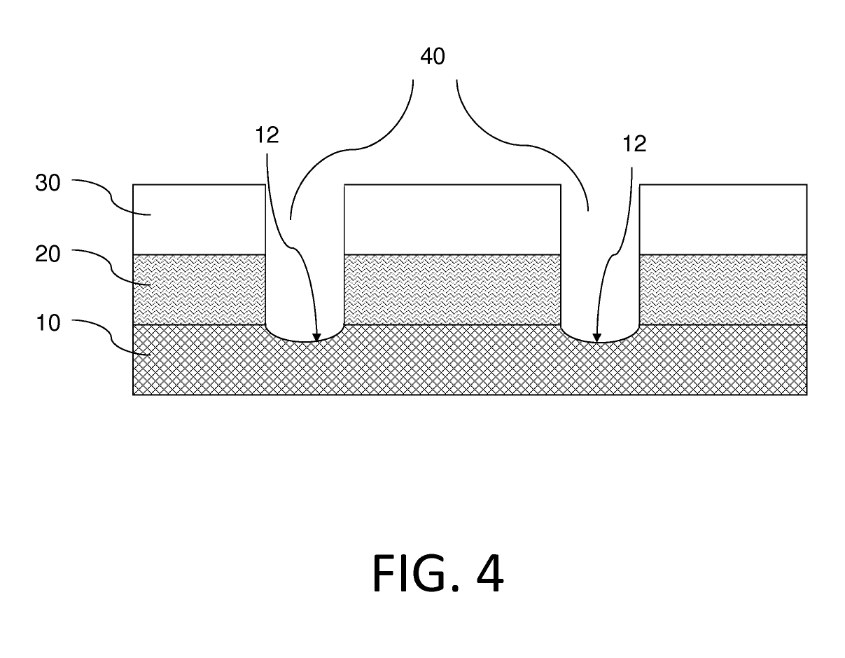

FIG. 4 is a schematic cross-sectional diagram of a contact hole structure over a semiconductor substrate illustrating the result of exposing the substrate to an incompletely sparged aqueous ammonia solution with a dissolved oxygen level of approximately 200 ppb to remove the tungsten oxide layer then rinsing the substrate with a low oxygen DI water. Due to the existence of oxygen, there is some attack on the underlying tungsten surface as indicated by the curved tungsten surfaces within contact holes 12.

### EXAMPLE 2 (COMPARATIVE EXAMPLE)

A 12 inch silicon wafer containing a tungsten layer, a tungsten oxide layer, two dielectric layers, and contact hole openings was placed in a sealed spin/rinse chamber atmospherically controlled to be low oxygen. An aqueous ammonia solution was then dispensed onto the wafer at a rate of 1 liter/minute for one minute under typical single wafer spin/etch conditions. The concentration of the ammonia solution was 0.7 M. This ammonia solution had not been completely sparged with nitrogen with calculated dissolved oxygen level is approximately 200 ppb. After dispensing the ammonia solution, the wafer was rinsed for 60 seconds with a low oxygen DI water, and was spun dry before exiting the atmospherically controlled chamber. The tungsten oxide layer was removed with a metal loss of greater than 10 angstroms from the bulk tungsten layer in the openings of the contact holes. These concaved tungsten surfaces due to this metal loss are clearly apparent within the interface at the openings of the contact holes in a cross sectioned TEM image of the wafer after above processing.

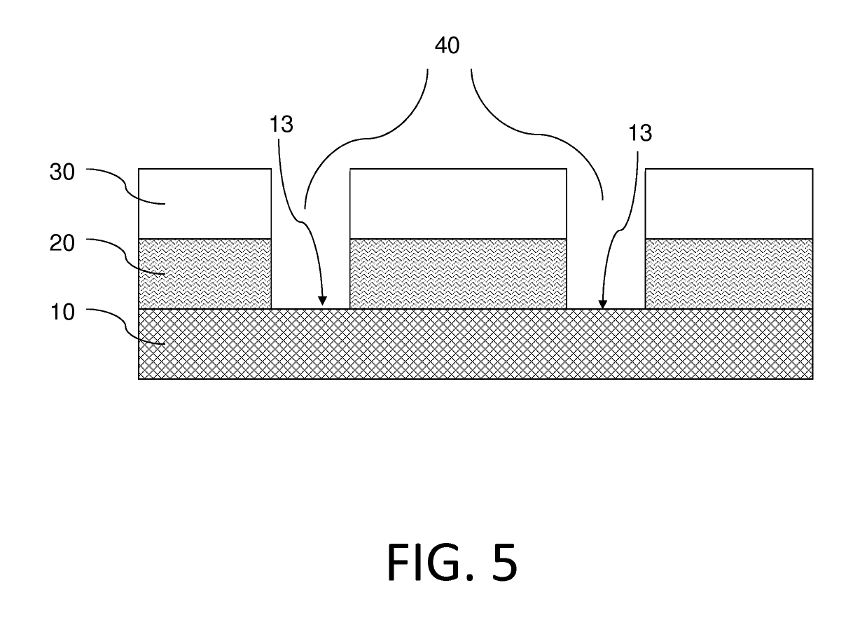

FIG. 5 exhibits the result of another one of our preferred embodiments of the present invention, and is a schematic cross-sectional diagram of a contact hole structure over a semiconductor substrate illustrating the result of exposing the substrate to a low oxygen HF/citric acid solution, exposing the substrate to a low oxygen aqueous ammonia solution to selectively remove the tungsten oxide layer, and then rinsing the substrate with a low oxygen DI water. Before applying the method of the present invention, the tungsten surfaces within contact holes may contain a tungsten oxide layer with various thicknesses. The substrate is first exposed to a low oxygen HF/citric acid solution for about 5 seconds to about 120 seconds with HF concentration in a range of about 0.01% to about 0.1% based on the total weight of the low oxygen HF/citric acid solution, the citric acid concentration may be in a range of about 0.05% to about 5%, and the oxygen is no more than 50 ppb. The substrate is then exposed to a low oxygen aqueous ammonia solution having an ammonia concentration in a range of about 0.01 M to about 2 M and oxygen level no more than 50 ppb to selectively remove tungsten oxide without etching the un-oxidized tungsten. After exposing the substrate to the low oxygen aqueous ammonia solution to selectively remove the metal oxide layer, the substrate is then rinsed with a low oxygen DI water. The low oxygen DI water may contain carbon dioxide. FIG. 5 shows the result after these steps again indicating no apparent film loss of underlying tungsten with the relatively unchanged tungsten surfaces within contact holes 13. One specific example is given below to illustrate this embodiment of the present invention. Since this example is given for illustrative purpose only, the invention is not limited to the specific details of the example.

### EXAMPLE 3

A 12 inch silicon wafer containing a tungsten layer, a tungsten oxide layer, two dielectric layers, and contact hole openings was placed in a sealed spin/rinse chamber atmospherically controlled to be low oxygen. A low oxygen HF/citric acid solution was then dispensed onto the wafer at a rate of 1 liter/minute for 18 seconds at 60° C. under typical single wafer spin/etch conditions. The HF concentration of the HF/citric acid solution was 0.05% based on the total weight of the low oxygen HF/citric acid solution, and the citric acid concentration was 1%. This HF/citric acid solution had been prior sparged with nitrogen to achieve a level of <50 ppb dissolved oxygen before dispensing on the wafer. After dispensing the HF/citric acid solution, the wafer was rinsed for 30 seconds with a low oxygen DI water, and was spun dry. A low oxygen aqueous ammonia solution was then dispensed onto the wafer at a rate of 1 liter/minute for one minute under typical single wafer spin/etch conditions. The concentration of the ammonia solution was 0.7 M. This ammonia solution had been prior sparged with nitrogen to achieve a level of <50 ppb dissolved oxygen before dispensing on the wafer. After dispensing the ammonia solution, the wafer was rinsed for 60 seconds with a low oxygen DI water, and was spun dry before exiting the atmospherically controlled chamber. The tungsten oxide layer was again removed without apparent film loss of the underlying tungsten layer as demonstrated in a cross sectioned TEM image of the wafer after the above processing. This repeat behavior reconfirms that oxygen level below 50 ppb provides a unique advantage in retention of un-oxidized tungsten metal during the removal of tungsten oxide in basic solution.

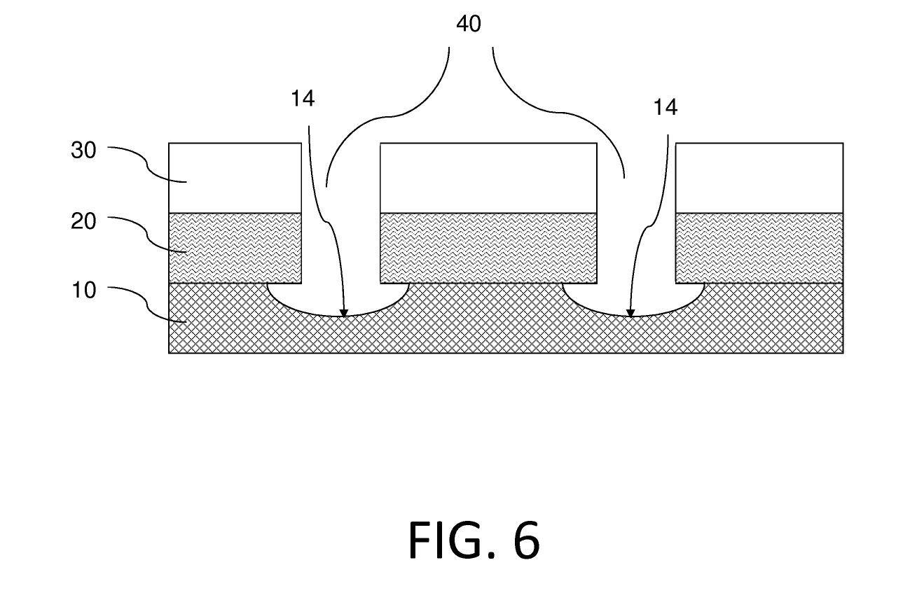

FIG. 6 is a schematic cross-sectional diagram of a contact hole structure over a semiconductor substrate illustrating the result of exposing the substrate to a hydrogen peroxide and sulfuric acid mixture to remove the tungsten oxide layer, and then rinsing the substrate with a DI water. Due to the existence of peroxide, there is a significant oxidation with subsequent attack on the underlying tungsten surface as indicated by the large eroded tungsten surfaces within contact holes 14.

### EXAMPLE 4 (COMPARATIVE EXAMPLE)

The spin/etch chamber was not sealed but open to atmospheric conditions during the spin/etch process. Due to the level of hydrogen peroxide in solution, the hydrogen peroxide dominated the oxidation behavior of the solution. An aqueous solution of 0.00075 w/w % of H202 in 0.048 w/w % H₂SO₄ at 45° C. was dispensed on a 12 inch wafer containing a tungsten layer, a tungsten oxide layer, two dielectric layers, and contact hole openings at a rate of 2 liters/minute for 90 seconds. Typical single wafer spin/etch conditions were used during this 90 second etch, and subsequently a 60 second rinse/dry step followed the etch step before the wafer was removed from the spin/etch system. The tungsten oxide layer was removed with significant film loss of the tungsten layer in the openings of the contact holes. Significantly eroded tungsten surfaces were shown on the openings of the contact holes in a cross sectioned TEM image of the wafer after above processing.

1. A method of removing metal oxide, comprising:
providing a substrate containing a metal oxide layer over a metal layer;
exposing the substrate to a low oxygen aqueous ammonia solution to selectively remove the metal oxide layer, wherein the low oxygen aqueous ammonia solution has an ammonia concentration in a range of about 0.01 M to about 2.0 M; and
rinsing the substrate with a DI water.

2. The method of claim 1, wherein the metal oxide is tungsten oxide and the metal is tungsten.

3. The method of claim 1, wherein the step of exposing the substrate to a low oxygen aqueous ammonia solution includes either sparging with nitrogen or argon, or vacuum degas of an aqueous ammonia solution to produce the low oxygen aqueous ammonia solution.

4. (canceled)

5. The method of claim 1, wherein the low oxygen aqueous ammonia solution has an ammonia concentration in a range of about 0.1 M to about 1.0 M.

6. The method of claim 1, wherein the low oxygen aqueous ammonia solution has oxygen level no more than 50 ppb.

7. The method of claim 1, wherein the low oxygen aqueous ammonia solution further comprises a corrosion inhibitor.

8. The method of claim 7, wherein the corrosion inhibitor is selected from a group consisting of triazole compound, benzotriazole compound, imidazole compound, tetrazole compound, thiazole compound, oxazole compound, pyrazole compound, and pyridine compound.

9. The method of claim 1, wherein the DI water comprises carbon dioxide.

10. The method of claim 1, wherein the substrate is exposed to the low oxygen aqueous ammonia solution in a time range from about 10 seconds to about 300 seconds.

11. A method of removing metal oxide, comprising:
providing a substrate containing a metal oxide layer over a metal layer;
exposing the substrate to a low oxygen HF/organic acid solution;
exposing the substrate to a low oxygen aqueous ammonia solution to selectively remove the metal oxide layer, wherein the low oxygen aqueous ammonia solution has an ammonia concentration in a range of about 0.01 M to about 2.0 M; and
rinsing the substrate with a DI water.

12. The method of claim 11, wherein the metal oxide is tungsten oxide and the metal is tungsten.

13. The method of claim 11, wherein the step of exposing the substrate to a low oxygen aqueous ammonia solution includes either sparging with nitrogen or argon, or vacuum degas of an aqueous ammonia solution to produce the low oxygen aqueous ammonia solution.

14. The method of claim 11, wherein the low oxygen aqueous ammonia solution has an ammonia concentration in a range of about 0.1 M to about 1.0 M.

15. The method of claim 11, wherein the low oxygen aqueous ammonia solution has an oxygen level no more than 50 ppb.

16. The method of claim 11, wherein the low oxygen aqueous ammonia solution further comprises a corrosion inhibitor selected from a group consisting of triazole compound, benzotriazole compound, imidazole compound, tetrazole compound, thiazole compound, oxazole compound, pyrazole compound and pyridine compound.

17. The method of claim 11, wherein the low oxygen HF/organic acid solution further comprises a compound having two or more carboxyl groups separated by at least one carbon.

18. The method of claim 17, wherein the compound having two or more carboxyl groups separated by at least one carbon is selected from a group consisting of malonic acid, succinic acid, glutaric acid, adipic acid, citric acid, isocitric acid, and 1-hydroxy-1,1,2-ethanetricarboxylic acid, and 1,2,3,4-butanetetracarboxylic acid.

19. The method of claim 11, wherein the low oxygen HF/organic acid solution has an oxygen level no more than 50 ppb.

20. The method of claim 11, wherein the DI water comprises carbon dioxide.

21. The method of claim 11, wherein the substrate is exposed to the low oxygen aqueous ammonia solution in a time range from about 10 seconds to about 300 seconds.
